(19) United States
(12) Patent Application Publication
(10) Pub. No.: US 2026/0204525 A1
(43) Pub. Date: Jul. 16, 2026

(54) PLASMA PROCESSING APPARATUS AND ETCHING METHOD

(71) Applicant: Tokyo Electron Limited, Tokyo (JP)

(72) Inventors: Mayo SATO, Miyagi (JP); Yusuke TAKINO, Miyagi (JP); Kazuya YAMADA, Miyagi (JP); Cedric THOMAS, Hillsboro, OR (US); Masahiko TAKAHASHI, Miyagi (JP)

(73) Assignee: Tokyo Electron Limited, Tokyo (JP)

(21) Appl. No.: 19/562,905

(22) Filed: Mar. 11, 2026

Related U.S. Application Data
(63) Continuation of application No. PCT/JP2025/029140, filed on Aug. 20, 2025.

(30) Foreign Application Priority Data
Sep. 3, 2024 (JP) 2024-151740

(51) Int. Cl. H01J 37/32; H10P 50/26

(52) U.S. Cl. CPC H01J 37/32715; H01J 37/32082; H01J 37/32449; H10P 50/268; H01J 2237/334

(57) ABSTRACT

A plasma processing apparatus includes a chamber; a substrate support; a gas supply to supply a processing gas into the chamber; a first radio-frequency power supply to supply first radio-frequency power to form the processing gas into a plasma; a pulsed-voltage source to apply a pulsed voltage being a pulsed direct current voltage to the substrate support; a second radio-frequency power supply configured to supply second radio-frequency power to the substrate support; and controller circuitry to perform, during etching of the substrate, control of the gas supply to supply the processing gas into the chamber, the first radio-frequency power supply to supply the first radio-frequency power to form the processing gas in the chamber into a plasma, the pulsed-voltage source to apply the pulsed voltage to the substrate support, and the second radio-frequency power supply to supply the second radio-frequency power in a manner superimposed on the pulsed voltage.

### CROSS-REFERENCE TO RELATED APPLICATIONS

This application is a continuation application of International Application PCT/JP2025/029140, filed on Aug. 20, 2025, and designating the U.S., and claims priority to Japanese Application No. 2024-151740, filed on Sep. 3, 2024, the entire contents of each of which are incorporated herein by reference.

### FIELD

The present disclosure relates to a plasma processing apparatus and an etching method.

### BACKGROUND

Patent Literature 1 below describes a plasma processing apparatus including a chamber, a first matching circuit, a second matching circuit, a first radio-frequency (RF) generator, a second RF generator, and a third RF generator. The first matching circuit and the second matching circuit are coupled to the chamber. The first RF generator is coupled to the first matching circuit to generate a first RF pulse signal including multiple pulse cycles. Each of the multiple pulse cycles includes a first period, a second period, and a third period. The first RF pulse signal has a first power level in the first period, a second power level in the second period, and a third power level in the third period. The first period is less than or equal to 30 μs. The second RF generator is coupled to the second matching circuit to generate a second RF pulse signal including the multiple pulse cycles. The second RF pulse signal has a lower frequency than the first RF pulse signal. The second RF pulse signal has a fourth power level in the first period and a fifth power level in at least one of the second period or the third period. The third RF generator is coupled to the second matching circuit to generate a third RF pulse signal including the multiple pulse cycles. The third RF pulse signal has a lower frequency than the second RF pulse signal. The third pulse signal has a sixth power level in the second period and a seventh power level in at least one of the first period or the third period.

Patent Literature 1: Japanese Unexamined Patent Application Publication No. 2022-048032

### SUMMARY

A plasma processing apparatus according to one aspect of the present disclosure includes a chamber; a substrate support in the chamber, the substrate support to support a substrate; a gas supply to supply a processing gas into the chamber; a first radio-frequency power supply configured to supply first radio-frequency power to form the processing gas in the chamber into a plasma; a pulsed-voltage source configured to apply a pulsed voltage being a pulsed direct current voltage to the substrate support; a second radio-frequency power supply configured to supply second radio-frequency power to the substrate support; and controller circuitry configured to perform, during etching of the substrate, control of the gas supply to supply the processing gas into the chamber, the first radio-frequency power supply to supply the first radio-frequency power to form the processing gas in the chamber into a plasma, the pulsed-voltage source to apply the pulsed voltage to the substrate support, and the second radio-frequency power supply to supply the second radio-frequency power in a manner superimposed on the pulsed voltage.

### BRIEF DESCRIPTION OF DRAWINGS

The scope of the present disclosure is best understood from the following detailed description of exemplary embodiments when read in conjunction with the accompanying drawings.

FIG. 1 is a diagram of an inductively coupled plasma processing apparatus, illustrating an example structure.

FIG. 2A is a diagram of a substrate W in a first embodiment, showing example etching.

FIG. 2B is a diagram of the substrate W in the first embodiment, showing example etching.

FIG. 3A is a diagram of the substrate W in the first embodiment, showing example etching.

FIG. 3B is a diagram of the substrate W in the first embodiment, showing example etching.

FIG. 4A is a graph showing an example change in the potential of a substrate W with an etching method in a first reference example.

FIG. 4B is a schematic diagram showing the movement of ions and radicals in a plasma with the etching method in the first reference example.

FIG. 4C is a graph showing an example energy distribution of ions with the etching method in the first reference example.

FIG. 5A is a graph showing an example change in the potential of a substrate W with an etching method in a second reference example.

FIG. 5B is a schematic diagram showing the movement of ions and radicals in a plasma with the etching method in the second reference example.

FIG. 5C is a graph showing an example energy distribution of ions with the etching method in the second reference example.

FIG. 6 is a diagram of an example residue remaining on the etched substrate in the first embodiment.

FIG. 7A is a graph showing an example change in the potential of the substrate W with the etching method according to the first embodiment.

FIG. 7B is a graph showing an example energy distribution of ions with the etching method according to the first embodiment.

FIG. 8A is a diagram describing the processing conditions for the etching method in the first reference example in a first verification.

FIG. 8B is a diagram describing the processing conditions for the etching method according to the first embodiment in the first verification.

FIG. 9A is a diagram describing the processing conditions for the etching method according to the first embodiment in a second verification.

FIG. 9B is a diagram describing the processing conditions for the etching method according to the first embodiment in the second verification.

FIG. 10A is a diagram describing the processing conditions for the etching method according to the first embodiment in a third verification.

FIG. 10B is a diagram describing the processing conditions for the etching method according to the first embodiment in the third verification.

FIG. 11 is a flowchart of an example order of etching according to the first embodiment.

FIG. 12A is a graph showing an example change in the potential of a substrate W with an etching method according to a second embodiment.

FIG. 12B is a graph showing an example energy distribution of ions with the etching method according to the second embodiment.

FIG. 13A is a graph showing changes in the potential of the substrate W in response to changes in the amplitude of a bias direct current (DC) signal.

FIG. 13B is a graph showing changes in the energy distribution of ions in response to changes in the amplitude of the bias DC signal.

FIG. 14A is a graph showing changes in the potential of the substrate W in response to changes in an on-time of the bias DC signal.

FIG. 14B is a graph showing changes in the energy distribution of ions in response to changes in the on-time of the bias DC signal.

FIG. 15A is a graph showing changes in the potential of the substrate W in response to changes in the amplitude of a bias radio-frequency (RF) signal.

FIG. 15B is a graph showing changes in the energy distribution of ions in response to changes in the amplitude of the bias RF signal.

FIG. 16A is a graph showing changes in the potential of the substrate W in response to changes in an off-time of the bias DC signal.

FIG. 16B is a graph showing changes in the energy distribution of ions in response to changes in the off-time of the bias DC signal.

FIG. 17 is a graph showing changes in the potential of the substrate W in response to changes in a superimposition period in which the bias RF signal is superimposed.

FIG. 18 is a graph showing changes in the potential of the substrate W in response to changes in the superimposition period in which the bias RF signal is superimposed.

### DESCRIPTION OF EMBODIMENTS

A plasma processing apparatus and an etching method according to one or more embodiments of the present application will be described below in detail with reference to the drawings. The plasma processing apparatus and the etching method described herein are not limited to the embodiments below.

The plasma processing apparatus receives a substrate placed on a substrate support in a chamber and generates a plasma in the chamber to perform plasma processing such as etching. In manufacturing of semiconductor devices, higher verticality is to be achieved in the processing performance. A known etching method implementable with a plasma processing apparatus includes applying a direct current (DC) voltage of a pulsed rectangular wave to the substrate support to etch a substrate. Applying a DC voltage of a rectangular wave to the substrate support during etching of the substrate improves the verticality of ions, achieving higher verticality in the processing performance.

However, ions with improved verticality may cause a residue remaining at a corner of the etched bottom. A technique for reducing such a residue is thus awaited.

### First Embodiment

### Apparatus Structure

An example plasma processing apparatus according to one or more embodiments of the present disclosure will now be described. In the embodiments described below, the plasma processing apparatus according to one or more embodiments of the present disclosure is a plasma processing system with a system configuration.

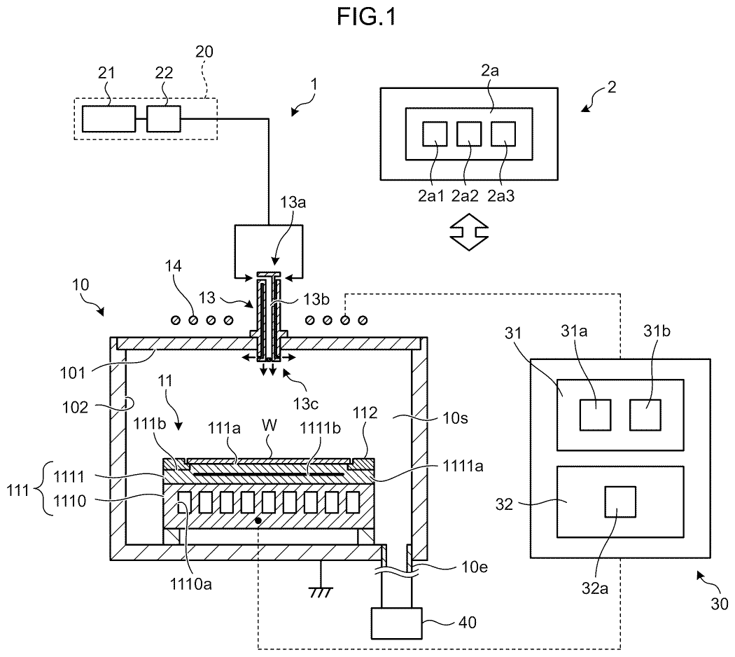

An example structure of the plasma processing system will be described below. FIG. 1 is a diagram of an inductively coupled plasma processing apparatus, illustrating an example structure.

The plasma processing system includes an inductively coupled plasma processing apparatus 1 and a controller 2. The inductively coupled plasma processing apparatus 1 includes a plasma processing chamber 10, a gas supply 20, a power supply 30, and an exhaust system 40. The plasma processing chamber 10 corresponds to a chamber in an aspect of the present disclosure. The plasma processing chamber 10 includes a dielectric window. The plasma processing apparatus 1 also includes a substrate support 11, a gas guide unit, and an antenna 14. The substrate support 11 is located in the plasma processing chamber 10. The antenna 14 is located on or above the plasma processing chamber 10 (more specifically, on or above a dielectric window 101). The plasma processing chamber 10 has a plasma processing space 10s defined by the dielectric window 101, a sidewall 102 of the plasma processing chamber 10, and the substrate support 11. The plasma processing chamber 10 has at least one gas inlet for supplying at least one processing gas into the plasma processing space 10s and at least one gas outlet for discharging the gas from the plasma processing space. The plasma processing chamber 10 is grounded.

The substrate support 11 includes a body 111 and a ring assembly 112. The body 111 includes a central portion 111a for supporting a substrate W and an annular portion 111b for supporting the ring assembly 112. A wafer is an example of the substrate W. The annular portion 111b of the body 111 surrounds the central portion 111a of the body 111 as viewed in plan. The substrate W is placeable on the central portion 111a of the body 111. The ring assembly 112 is located on the annular portion 111b of the body 111 to surround the substrate W on the central portion 111a of the body 111. Thus, the central portion 111a is also referred to as a substrate support surface for supporting the substrate W. The annular portion 111b is also referred to as a ring support surface for supporting the ring assembly 112.

In one embodiment, the body 111 includes a base 1110 and an electrostatic chuck (ESC) 1111. The base 1110 includes a conductive member. The conductive member in the base 1110 may function as a bias electrode. The ESC 1111 is located on the base 1110. The ESC 1111 includes a ceramic member 1111a and an electrostatic electrode 1111b located inside the ceramic member 1111a. The ceramic member 1111a includes the central portion 111a. In one embodiment, the ceramic member 1111a also includes the annular portion 111b. The annular portion 111b may be included in another member surrounding the ESC 1111, such as an annular ESC or an annular insulating member. In this case, the ring assembly 112 may be located on the annular ESC or the annular insulating member, or may be located on both the ESC 1111 and the annular insulating member. At least one radio frequency (RF)/DC electrode coupled to an RF power supply 31 or a DC power supply 32, or both (described later) may be located inside the ceramic member 1111a. In this case, the RF/DC electrode functions as a bias electrode. The conductive member in the base 1110 and at least one RF/DC electrode may function as multiple bias electrodes. The electrostatic electrode 1111b may also function as a bias electrode. The substrate support 11 thus includes at least one bias electrode.

The ring assembly 112 includes one or more annular members. In one embodiment, the one or more annular members include one or more edge rings and at least one cover ring. The edge rings are formed from a conductive material or an insulating material. The cover ring is formed from an insulating material.

The substrate support 11 may include a temperature controller that adjusts the temperature of at least one of the ESC 1111, the ring assembly 112, or the substrate to a target temperature. The temperature controller may include a heater, a heat transfer medium, a channel 1110a, or a combination of these. The channel 1110a carries a heat transfer fluid such as brine or a gas. In one embodiment, the channel 1110a is defined inside the base 1110, and one or more heaters are located inside the ceramic member 1111a in the ESC 1111. The substrate support 11 may include a heat transfer gas supply to supply a heat transfer gas into a space between the back surface of the substrate W and the central portion 111a.

The gas guide unit introduces at least one processing gas from the gas supply 20 into the plasma processing space 10s. In one embodiment, the gas guide unit includes a central gas injector (CGI) 13. The CGI 13 is located above the substrate support 11 and installed in a central opening in the dielectric window 101. The CGI 13 has at least one gas inlet 13a, at least one gas channel 13b, and at least one gas guide 13c. The processing gas supplied to the gas inlet 13a passes through the gas channel 13b and is introduced into the plasma processing space 10s through the gas guide 13c. In addition to or in place of the CGI 13, the gas guide unit may include one or more side gas injectors (SGIs) installed in one or more openings in the sidewall 102.

The gas supply 20 may include at least one gas source 21 and at least one flow controller 22. In one embodiment, the gas supply 20 supplies at least one processing gas from each gas source 21 to the gas guide unit through the corresponding flow controller 22. The flow controller 22 may be, for example, a mass flow controller or a pressure-based flow controller. The gas supply 20 may further include one or more flow rate modulators that cause at least one processing gas to be supplied at a modulated flow rate or in a pulsed manner.

The power supply 30 includes an RF power supply 31 coupled to the plasma processing chamber 10 through at least one impedance matching circuit. The RF power supply 31 provides at least one RF signal (RF power) to at least one bias electrode and the antenna 14. This generates a plasma from at least one processing gas supplied into the plasma processing space 10s. The RF power supply 31 may thus function as at least a part of a plasma generator that generates a plasma from one or more processing gases in the plasma processing chamber 10. A bias RF signal is provided to at least one bias electrode to generate a bias potential in the substrate W, thus drawing ions in the generated plasma toward the substrate W.

In one embodiment, the RF power supply 31 includes a first RF generator 31a and a second RF generator 31b. The first RF generator 31a is coupled to the antenna 14 to generate a source RF signal (source RF power) for plasma generation through at least one impedance matching circuit. In one embodiment, the source RF signal has a frequency in a range of 10 to 150 MHz. In one embodiment, the first RF generator 31 a may generate multiple source RF signals with different frequencies. The one or more generated source RF signals are provided to the antenna 14. The first RF generator 31a corresponds to a first RF power supply in an aspect of the present disclosure. The source RF signal corresponds to first RF power in an aspect of the present disclosure.

The second RF generator 31b is coupled to at least one bias electrode through at least one impedance matching circuit to generate a bias RF signal (bias RF power). The frequency of the bias RF signal may be the same as or different from the frequency of the source RF signal. In one embodiment, the bias RF signal has a lower frequency than the source RF signal. In one embodiment, the bias RF signal may have a frequency in a range of 1 to 100 MHz, and more specifically, in a range of 13 to 60 MHz. In one embodiment, the second RF generator 31b may generate multiple bias RF signals with different frequencies. The one or more generated bias RF signals are provided to at least one bias electrode. In various embodiments, at least one of the source RF signal or the bias RF signal may be pulsed. The second RF generator 31b corresponds to a second RF power supply in an aspect of the present disclosure. The bias RF signal corresponds to second RF power in an aspect of the present disclosure.

The power supply 30 may include the DC power supply 32 coupled to the plasma processing chamber 10. The DC power supply 32 includes a bias DC generator 32a. In one embodiment, the bias DC generator 32a is coupled to at least one bias electrode to generate a bias DC signal. The generated bias DC signal is applied to at least one bias electrode.

In various embodiments, the bias DC signal may be pulsed. In this case, the sequence of pulsed voltage is applied to at least one bias electrode. The pulsed voltage may have rectangular, trapezoidal, or triangular pulse waveforms, or a combination of these.

The bias DC generator 32a provides a bias DC signal of a pulsed DC voltage. For example, the bias DC generator 32a periodically switches a negative DC voltage on and off to provide a pulsed bias DC signal. In one embodiment, the bias DC generator 32a can apply a DC voltage with a negative value. The bias DC generator 32a switches application of a DC voltage on and off in predetermined cycles to apply, as a bias DC signal, a pulsed voltage with a predetermined frequency to the bias electrode in the base 1110. The bias DC signal may have a frequency in a range of 100 to 1200 kHz, or more specifically, in a range of 400 to 800 Hz. The bias DC generator 32a can change the duty cycle of the bias DC signal by changing the ratio of on-time and off-time in one cycle. The bias DC generator 32a corresponds to a pulsed-voltage source in an aspect of the present disclosure. The bias DC signal corresponds to a pulsed voltage in an aspect of the present disclosure.

The antenna 14 includes one or more coils. In one embodiment, the antenna 14 may include an outer coil and an inner coil that are coaxial with each other. In this case, the RF power supply 31 may be coupled to both the outer coil and the inner coil, or either the outer coil or the inner coil. When the RF power supply 31 is coupled to both the outer coil and the inner coil, a single RF generator may be connected to both the outer coil and the inner coil, or separate RF generators may be connected respectively to the outer coil and the inner coil.

The plasma processing apparatus 1 provides a source RF signal for plasma generation from the first RF generator 31a to the antenna 14 during plasma processing. The plasma processing apparatus 1 also provides a pulsed bias DC signal from the bias DC generator 32a to the lower electrode in the base 1110 during plasma processing. The plasma processing apparatus 1 also provides a bias RF signal from the second RF generator 31b in a manner superimposed on the bias DC signal during plasma processing.

The exhaust system 40 is connectable to, for example, a gas outlet 10e in the bottom of the plasma processing chamber 10. The exhaust system 40 may include a pressure control valve and a vacuum pump. The pressure control valve regulates the pressure in the plasma processing space 10s. The vacuum pump may be a turbomolecular pump, a dry pump, or a combination of these.

The controller 2 processes computer-executable instructions that cause the plasma processing apparatus 1 to perform various steps described in one or more embodiments of the present disclosure (herein “controller” means the same as “controller circuitry”). The controller 2 may control the components of the plasma processing apparatus 1 to perform the various steps described herein. In one embodiment, some or all of the components of the controller 2 may be included in the plasma processing apparatus 1. The controller 2 may include a processor 2a1, a storage 2a2, and a communication interface 2a3. The controller 2 is implemented by, for example, a computer 2a. The processor 2a1 may perform various control operations by loading programs from the storage 2a2 and executing the loaded programs. The programs may be prestored in the storage 2a2 or may be obtained through a medium as appropriate. The obtained programs are stored into the storage 2a2 to be loaded from the storage 2a2 and executed by the processor 2a1. The medium may be one of various storage media readable by the computer 2a or a communication line connected to the communication interface 2a3. The processor 2a1 may be a central processing unit (CPU). The storage 2a2 may include a random-access memory (RAM), a read-only memory (ROM), a hard disk drive (HDD), a solid-state drive (SSD), or a combination of these. The communication interface 2a3 may communicate with the plasma processing apparatus 1 through a communication line such as a local area network (LAN). The controller/controller circuitry 2 can be programmable circuitry (e.g., embedded processor) or fixed circuitry (e.g., ASIC or PAL). In an exemplary embodiment, the controller/controller circuitry 2 can include one or more programmable processors/controllers.

### Plasma Processing Procedure

The procedure for performing plasma processing such as plasma etching of the substrate W with the plasma processing system according to an embodiment will now be described briefly. The substrate W is loaded into, with a transferrer such as a transfer arm, the plasma processing chamber 10 through a port for loading and unloading and placed on the central portion 111a of the substrate support 11. The exhaust system 40 exhausts the plasma processing chamber 10 to a predetermined degree of vacuum.

To etch the substrate W, the controller 2 controls the gas supply 20 to supply a processing gas from the gas supply 20 into the plasma processing chamber 10. For example, the storage 2a2 stores a recipe for plasma processing of the substrate. The recipe stores a gas species and a flow rate used for etching. For example, the controller 2 reads the recipe from the storage 2a2, and supplies a gas selected from the gas species in the recipe from the gas supply 20 into the plasma processing chamber 10 at the flow rate stored in the recipe.

The controller 2 controls the first RF generator 31a to provide a source RF signal from the first RF generator 31a to form the processing gas in the plasma processing chamber 10 into a plasma. For example, the recipe stores power of the source RF signal. The controller 2 causes the first RF generator 31a to supply a source RF signal to the antenna 14 with the power stored in the recipe to generate a magnetic force in the plasma processing chamber 10. The processing gas in the plasma processing chamber 10 is then formed into a plasma to generate an inductively coupled plasma.

The controller 2 controls the bias DC generator 32a to provide a bias DC signal from the bias DC generator 32a to the substrate support 11. The controller 2 controls the bias DC generator 32a to control the duty cycle of the bias DC signal. For example, the controller 2 may control the duty cycle of the bias DC signal to be 10 to 80%, or more specifically, 10 to 20%. For example, the recipe stores a duty cycle of the bias DC signal. The controller 2 reads the recipe from the storage 2a2, and provides the bias DC signal with the duty cycle stored in the recipe from the bias DC generator 32a.

The controller 2 controls the second RF generator 31b to provide a bias RF signal to the substrate support 11 in a manner superimposed on the bias DC signal. For example, the recipe stores power of the bias RF signal. For example, the controller 2 reads the recipe from the storage 2a2 and causes the second RF generator 31b to provide a bias RF signal with the power stored in the recipe.

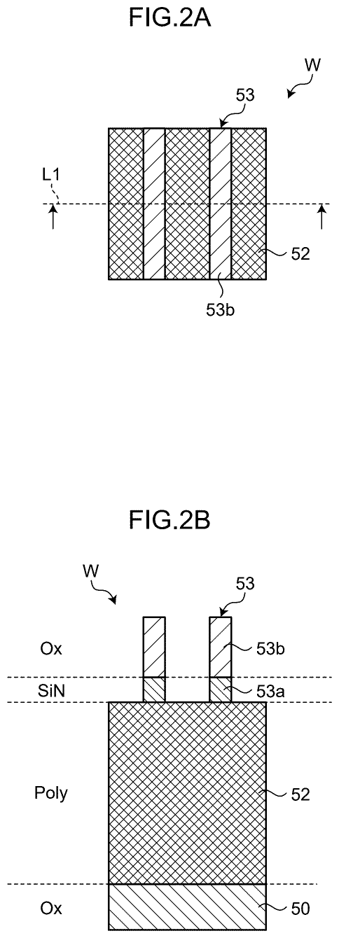

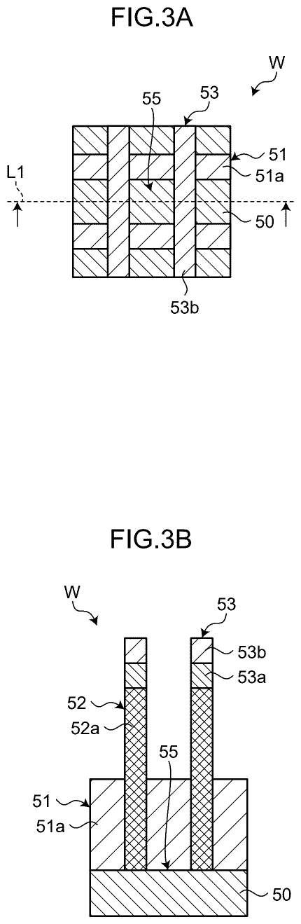

Example etching of a substrate W according to a first embodiment will now be described. FIGS. 2A to 3B are diagrams of the substrate W in the first embodiment, showing example etching. FIG. 2A is a plan view of the substrate W before etching as viewed from above. FIG. 2B is a cross-sectional view of the substrate W before etching taken along dashed line L1 in FIG. 2A. FIG. 3A is a plan view of the substrate W after etching as viewed from above. FIG. 3B is a cross-sectional view of the substrate W after etching taken along dashed line L1 in FIG. 3A.

The substrate W before etching includes an underlying layer 50 and a fin structure 51 including multiple fins 51a on the underlying layer 50. The substrate W before etching includes a gate material 52 deposited on the fin structure 51 and masks 53 formed on the gate material 52. The fin structure 51 is buried in the gate material 52. The underlying layer 50 is a stop layer that restricts etching into a lower layer. The underlying layer 50 is formed from, for example, an oxide (Ox). The underlying layer 50 may be, for example, a silicon oxide film (hereinafter “film” means the same as “layer”). The underlying layer 50 may be a SiN film, an organic film, or a metal film such as a tungsten film. The fin structure 51 is formed from, for example, an oxide covering the surface of the silicon layer. The fins 51a in the fin structure 51 are arranged in parallel in a first direction. The gate material 52 may be, for example, polycrystalline silicon (polysilicon). The masks 53 include, for example, oxide layers 53b (Ox) stacked on SiN layers 53a. The masks 53 are formed in parallel with clearances in a second direction intersecting with the first direction.

FIGS. 3A and 3B show the substrate W with the gate material 52 etched to the underlying layer 50 using the masks 53 as masks. Examples of a pressure condition for etching the substrate W and a processing gas are described below. In the values below, 1 sccm is about 1.69×10 m⁻³ pa·m³/s, and 1 mTorr is about 0.133 Pa.

### Pressure Condition

Pressure in the plasma processing chamber 10:50 to 100 mTorr

### Processing Gas

Cl₂ gas: 100 to 210 sccm
HBr gas: 70 to 150 sccm
O₂ gas: 30 to 60 sccm
Ar gas: 50 to 300 sccm

As shown in FIGS. 3A and 3B, the gate material 52 remains as gate portions 52a directly below the masks 53 after etching. The remaining gate portions 52a serve as gates. In the substrate W, rectangular portions 55 each surrounded by the masks 53 and the fins 51a reach the underlying layer 50.

An etching method as a reference example will now be described. The reference example will be described focusing on the differences from the etching method according to the first embodiment.

An etching method in a first reference example will be described first. A known etching method includes applying RF power as a bias to the substrate support 11 to etch a substrate W. For example, the etching method in the first reference example includes supplying a source RF signal from the first RF generator 31a to form a processing gas in the plasma processing chamber 10 into a plasma during etching of the substrate W. The etching method in the first reference example includes providing a bias RF signal from the second RF generator 31b to the lower electrode in the base 1110 without providing a bias DC signal from the bias DC generator 32a.

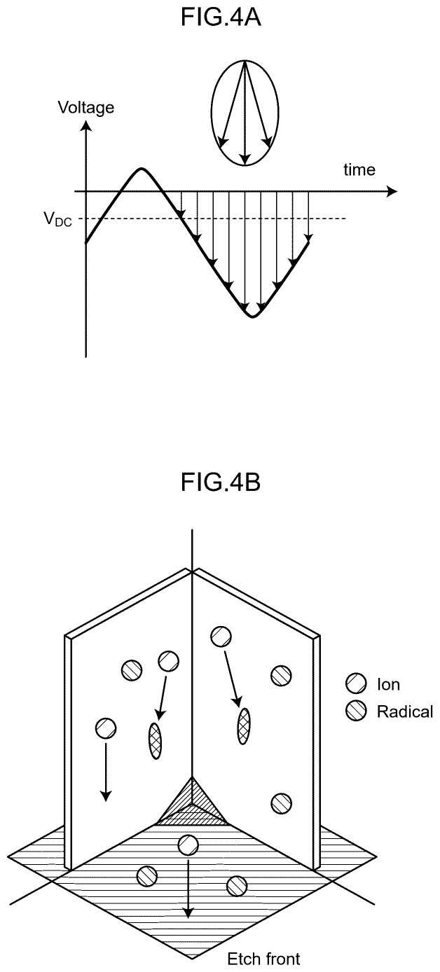

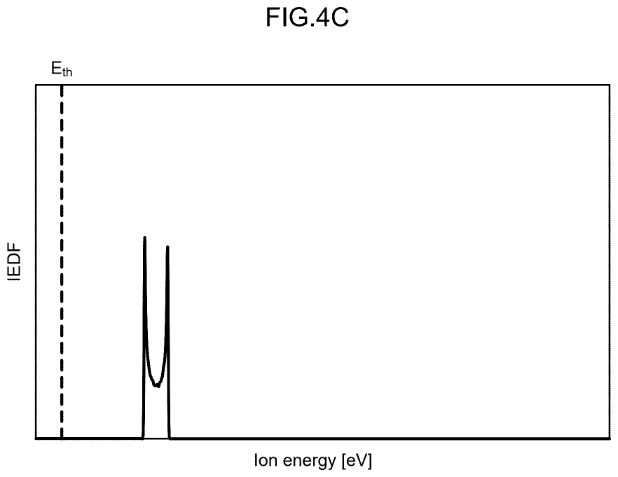

FIG. 4A is a graph showing an example change in the potential of the substrate W with the etching method in the first reference example. The bias RF signal as RF power is provided to the lower electrode in the base 1110 to change the potential of the substrate W sinusoidally in response to changes in the bias RF signal.

FIG. 4B is a schematic diagram showing the movement of ions and radicals in a plasma with the etching method in the first reference example. In FIG. 4B, the etch front refers to a position closer to an etching target, such as the substrate W. Ions and radicals in a plasma are drawn toward the substrate W by the potential of the substrate W and etch the substrate W. With the etching method in the first reference example, the potential of the substrate W changes sinusoidally to scatter ions and radicals, increasing the incident angle of ions and radicals incident on the substrate W. The etching method in the first reference example has a wider energy distribution of ions and radicals incident on the substrate W.

FIG. 4C is a diagram of an example energy distribution of ions with the first reference etching method. FIG. 4C shows example results of the ion energy distribution function (IEDF) with the etching method in the first reference example. The horizontal axis indicates the energy of ions (eV), with higher energy rightward. The vertical axis indicates the number of ions, with more ions upward. FIG. 4C shows the minimum ion energy used for etching the gate material 52 as a threshold Eₜₕ. The threshold Eₜₕ is, for example, 25 eV.

The etching method in the first reference example has an energy distribution of ions in a range higher than or equal to the threshold Eₜₕ, allowing etching of the gate material 52. However, the etching method has a peak at a lower energy level of the energy distribution and has a wide energy width in which the peak appears. The etching method in the first reference example thus has a wider energy distribution of ions incident on the substrate W.

The etching method in the first reference example thus has lower verticality in the processing performance. When the substrate W shown in FIGS. 2A to 3B is etched with the etching method in the first reference example, for example, the sidewalls of the gate portion 52a are also etched, increasing the roughness of the sidewalls of the gate portion 52a.

An etching method in a second reference example will now be described. In manufacturing of semiconductor devices, higher verticality is to be achieved in the processing performance. A known etching method thus includes applying a DC voltage of a pulsed rectangular wave to the substrate support 11 to etch a substrate. For example, the etching method in the second reference example includes supplying a source RF signal from the first RF generator 31a to form a processing gas in the plasma processing chamber 10 into a plasma during etching of the substrate W. The etching method in the second reference example includes providing a bias DC signal of a pulsed negative DC voltage from the bias DC generator 32a to the lower electrode in the base 1110 without providing a bias RF signal from the second RF generator 31b.

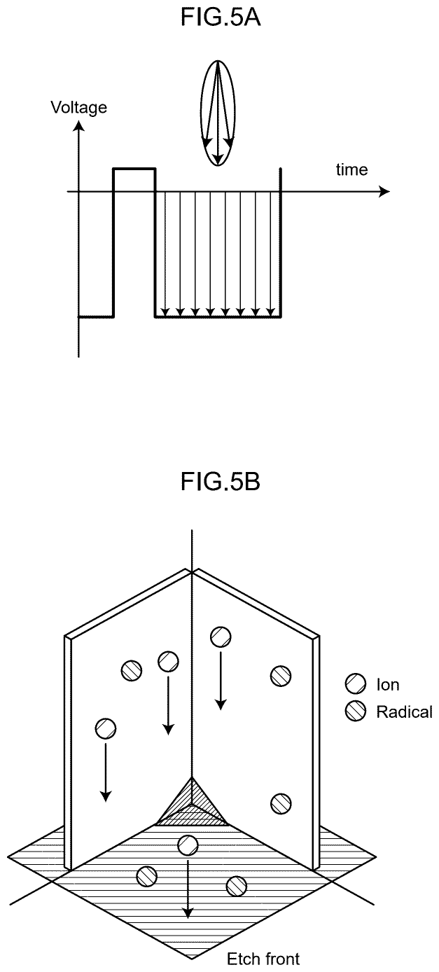

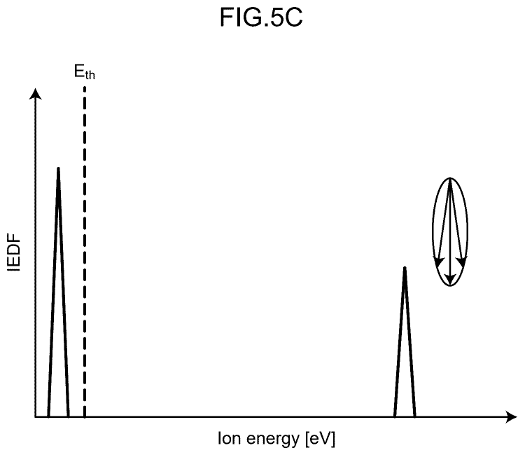

FIG. 5A is a graph showing an example change in the potential of the substrate W with the etching method in the second reference example. The bias DC signal of a pulsed negative DC voltage is provided to the lower electrode in the base 1110 to change the potential of the substrate W rectangularly in response to changes in the bias DC signal.

FIG. 5B is a schematic diagram showing the movement of ions and radicals in a plasma with the etching method in the second reference example. In FIG. 5B, the etch front refers to a position closer to an etching target, such as the substrate W. Ions and radicals in a plasma are drawn toward the substrate W by the potential of the substrate W and etch the substrate W. With the etching method in the second reference example, the potential of the substrate W changes rectangularly, improving the verticality of ions and radicals incident on the substrate W. The etching method in the second reference example has a narrower energy distribution of ions and radicals incident on the substrate W, and has a higher energy peak.

FIG. 5C is a graph showing an example energy distribution of ions with the etching method in the second reference example. FIG. 5C is a schematic graph of the IEDF with the etching method in the second reference example. The horizontal axis indicates the energy of ions (eV), with higher energy rightward. The vertical axis indicates the number of ions, with more ions upward. FIG. 5C shows the threshold Eₜₕ of the ion energy used for etching the gate material 52.

The etching method in the second reference example has peaks at a higher energy level and a lower energy level. At the lower energy level, the ion energy is less than or equal to the threshold Eₜₕ, thus not contributing to etching of the gate material 52. At the higher energy level, a higher peak appears in a narrower energy width. In other words, the etching method in the second reference example has a peak at a higher energy level with an acute energy distribution. This improves the verticality of ions and radicals incident on the substrate W.

The etching method in the second reference example has higher verticality of ions and radicals, thus achieving higher verticality in the processing performance. When the substrate W shown in FIGS. 2A to 3B is etched with the etching method in the second reference example, for example, the gate portion 52a can be etched vertically with lower roughness on the sidewalls of the gate portion 52a.

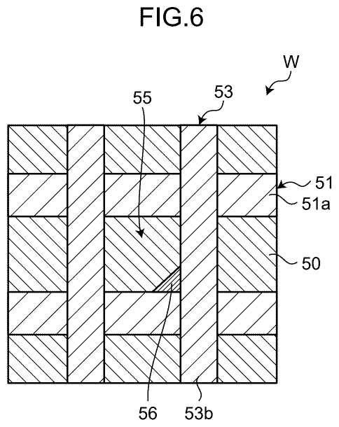

However, the etching method in the second reference example with improved verticality of ions in the processing performance may cause a residue remaining at a corner of the etched bottom. FIG. 6 is a diagram of an example residue remaining on the etched substrate W in the first embodiment. FIG. 6 is a plan view of the substrate W after etching as viewed from above. The substrate W after etching has a residue 56 of the gate material 52 remaining in each rectangular portion 55.

The etching method according to the first embodiment thus includes providing a bias DC signal of a pulsed negative DC voltage from the bias DC generator 32a to the lower electrode in the base 1110 during etching of the substrate W. The etching method according to the first embodiment also includes providing a bias RF signal from the second RF generator 31b in a manner superimposed on the bias DC signal.

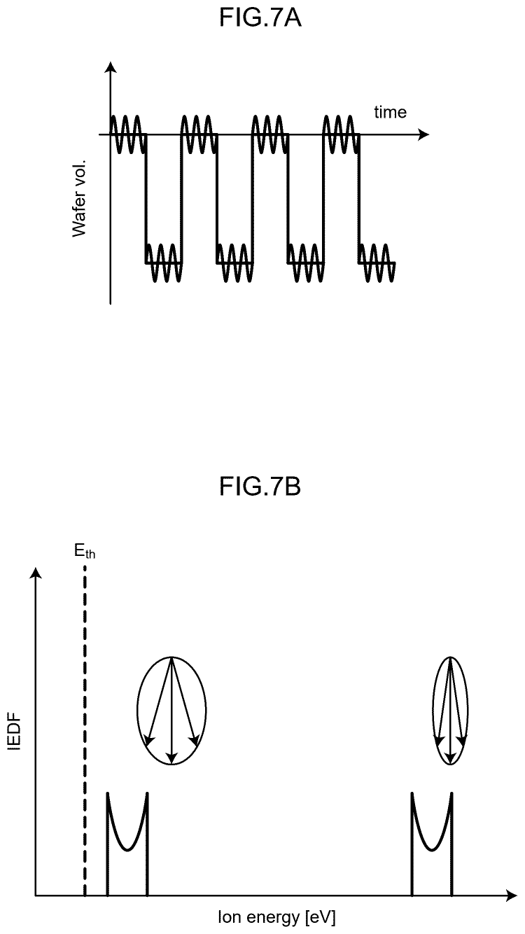

FIG. 7A is a graph showing an example change in the potential of the substrate W with the etching method according to the first embodiment. The bias DC signal of a puled negative DC voltage and the bias RF signal are provided to the lower electrode in the base 1110 in a manner superimposed on each other. The potential of the substrate W thus changes rectangularly in response to changes in the bias DC signal and oscillates in response to the bias RF signal.

FIG. 7B is a graph showing an example energy distribution of ions with the etching method according to the first embodiment. FIG. 7B is a schematic graph of the IEDF with the etching method according to the first embodiment. The horizontal axis indicates the energy of ions (eV), with higher energy rightward. The vertical axis indicates the number of ions, with more ions upward. FIG. 7B shows the threshold Eₜₕ of the ion energy used for etching the gate material 52.

The etching method according to the first embodiment has peaks at a higher energy level and a lower energy level. Each peak appears in a wider energy width. The etching method according to the first embodiment with a peak at the higher energy level can achieve higher verticality in the processing performance. With the etching method according to the first embodiment, the peak at the lower energy level is also higher than or equal to the threshold Eₜₕ. The peak also appears in a wider energy width, increasing the incident angle of ions incident on the substrate W. This allows efficient removal of the residue 56.

Example results of verifications obtained by actually etching the substrate W and observing the amount of the residue 56 will now be described.

In each verification, the substrates W were etched with the etching method according to the first embodiment and the etching method in the first reference example. The etching method according to the first embodiment includes two steps, or specifically, a residue removal step 1 and a residue removal step 2 performed in this order. The conditions commonly used for the verification of the residue removal step 1 and the residue removal step 2 are as follows for the source RF signal, the bias RF signal, and the bias DC signal.

### Common Conditions for Etching Method According to First Embodiment

### Conditions for Residue Removal Step 1

Source RF signal: frequency of 27 MHz, power of 300 W
Bias RF signal: frequency of 13 MHz, power of 400 W
Bias DC signal: frequency of 400 kHz, −500 V, duty cycle of 0 to 80%

### Conditions for Residue Removal Step 2

Source RF signal: frequency of 27 MHz, power of 500 W
Bias RF signal: frequency of 13 MHz, power of 270 W
Bias DC signal: frequency of 400 kHz, −500 V, duty cycle of 0 to 80%

The duty cycle of the bias DC signal is the ratio of an on-time in one cycle in which the signal is on and off at −500 V. The etching method according to the first embodiment includes the residue removal step 1 followed by the residue removal step 2. The duty cycle of the bias DC signal was different between the residue removal step 1 and the residue removal step 2.

The results of a first verification will be described first. In the first verification, substrates W were etched with the etching method in the first reference example and the etching method according to the first embodiment. The amounts of the residue 56 on the substrates W were compared.

In the first verification, the source RF signal and the bias RF signal were set as described below for the etching method in the first reference example.

### Conditions for Etching Method in First Reference Example

Source RF signal: frequency of 27 MHz, power of 500 W
Bias RF signal: frequency of 13 MHz, power of 270 W

In the first verification, the duty cycle of the bias DC signal was set as described below for the residue removal in step 1 and the residue removal in step 2 in the etching method according to the first embodiment.

### Conditions for Etching Method According to First Embodiment

### Conditions for Residue Removal Step 1

Bias DC signal: not applied (duty cycle of 0%)

### Conditions for Residue Removal Step 2

Bias DC signal: frequency of 400 kHz, −500 V, duty cycle of 80%

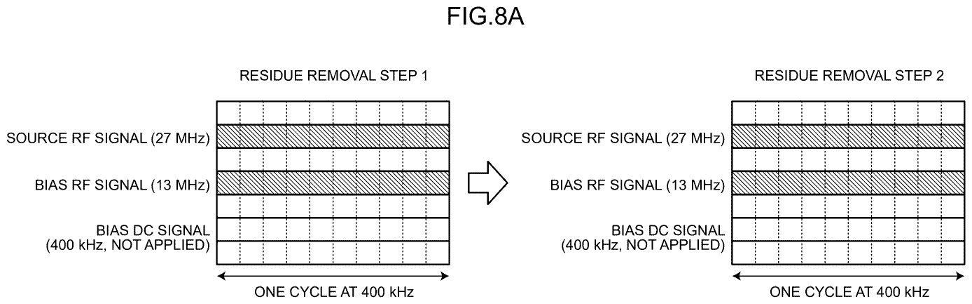

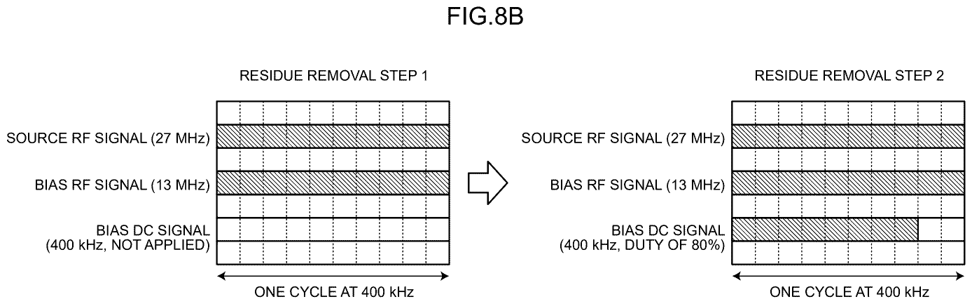

FIG. 8A is a diagram describing the processing conditions for the etching method in the first reference example in the first verification. FIG. 8A shows the conditions for the source RF signal, the bias RF signal, and the bias DC signal in the first reference example. The conditions are shown separately for the residue removal step 1 and the residue removal step 2 for easy comparison with the conditions for the etching method according to the first embodiment shown in FIG. 8B. FIG. 8A shows periods with hatched patterns in which the source RF signal and the bias RF signal are provided in one cycle at a frequency of 400 kHz during etching. The cycle corresponds to one cycle of the bias DC signal at a frequency of 400 kHz. With the etching method in the first reference example, the source RF signal and the bias RF signal are provided continuously during etching. The source RF signal and the bias RF signal thus have the hatched patterns for one cycle at a frequency of 400 kHz, indicating that the signals are constantly on. The source RF signal and the bias RF signal are provided as continuous waves (CWs). With the etching method in the first reference example, the bias DC signal is not applied in the residue removal step 1 and the residue removal step 2. The period of one cycle at a frequency of 400 kHz thus has no hatched pattern, indicating that the signal is continuously off.

FIG. 8B is a diagram describing the processing conditions for the etching method according to the first embodiment in the first verification. FIG. 8A shows the conditions for the source RF signal, the bias RF signal, and the bias DC signal with the etching method according to the first embodiment in the first verification. The conditions are shown separately for the residue removal step 1 and the residue removal step 2. In FIG. 8B, the conditions for the source RF signal, the bias RF signal, and the bias DC signal in the residue removal step 1 are the same as the conditions in the first reference example. In the residue removal step 1, the source RF signal and the bias RF signal are provided without the bias DC signal being applied. In the residue removal step 2, the source RF signal, the bias RF signal, and the bias DC signal are provided during etching. In the residue removal step 2, the bias DC signal is provided at a frequency of 400 kHz with the duty cycle of 80%. In FIG. 8B, the bias RF signal in the residue removal step 2 is on for 80% of the period of one cycle at a frequency of 400 kHz, as indicated by the hatched pattern.

In the first verification, the amount of the residue 56 on the substrate W processed with the etching method in the first reference was 1.61 nm, and the amount of the residue 56 on the substrate W processed with the etching method according to the first embodiment was 1.45 nm. This indicates that the etching method according to the first embodiment can reduce the amount of the residue 56 compared with the etching method in the first reference example.

The results of a second verification will now be described. In the second verification, the etching method according to the first embodiment has the same conditions as in the first reference example for the residue removal step 1. The duty cycle of the bias DC signal was set to 80% and 10% for the residue removal step 2. The substrates W were etched under the conditions, and the amounts of the residue 56 on the substrates W were compared.

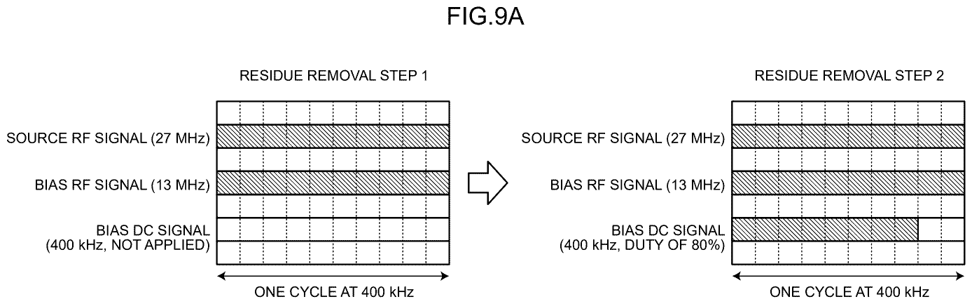

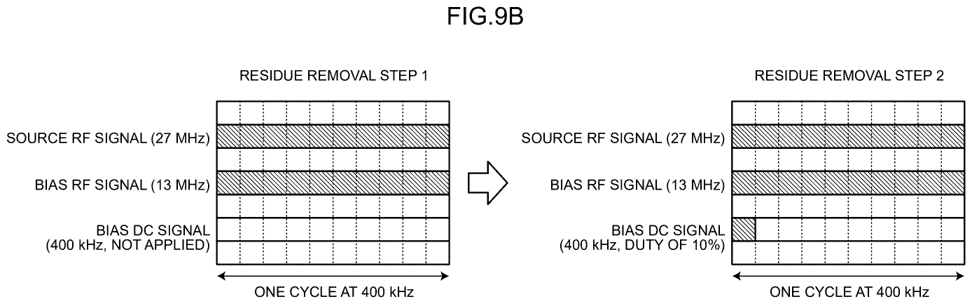

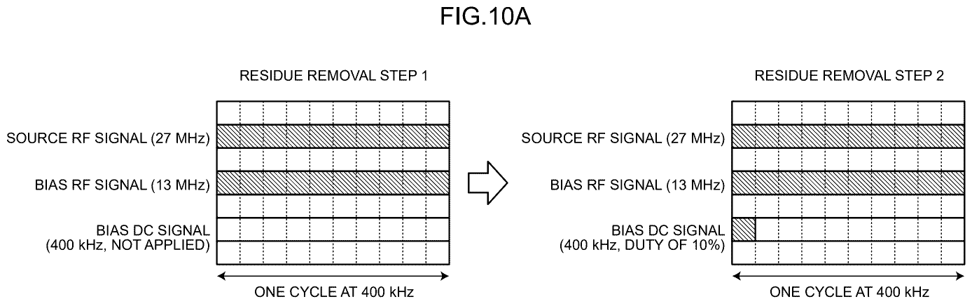

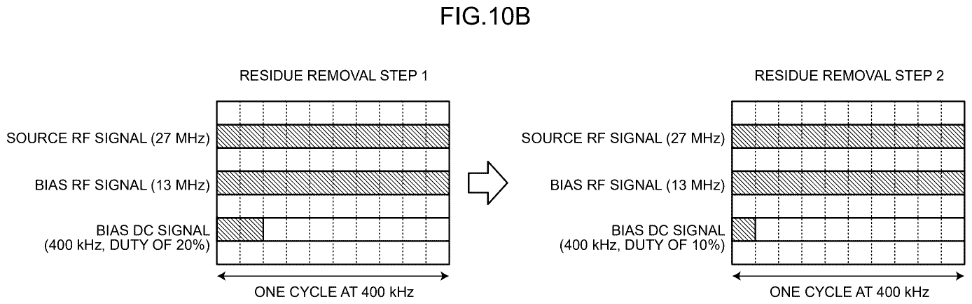

FIGS. 9A and 9B are diagrams describing the processing conditions for the etching method according to the first embodiment in the second verification. FIGS. 9A and 9B show the periods in which the source RF signal, the bias RF signal, and the bias DC signal are provided for the period of one cycle at a frequency of 400 kHz during etching. The conditions are shown separately for the residue removal step 1 and the residue removal step 2. In the second verification, the duty cycle of the bias DC signal during etching was set to 80% (FIGS. 9A) and 10% (FIG. 9B) for the residue removal step 2. The conditions for the residue removal step 1 are the same as the conditions in the first reference example.

In the second verification, the amount of the residue 56 on the substrate W was 2.21 nm for the duty cycle of 80% (FIG. 9A), and the amount of the residue 56 on the substrate W was 1.67 nm for the duty cycle of 10% (FIG. 9B). This indicates that the etching method according to the first embodiment can reduce the amount of the residue 56 with a bias DC signal having a lower duty cycle. For the duty cycle of 80%, the amounts of the residue 56 were different between the first verification and the second verification. This difference results from a slight difference in the structures of the substrates W used in the first verification and the second verification.

The results of a third verification will now be described. In the third verification, the duty cycle of the bias DC signal was set to 10% for the residue removal step 2 in the etching method according to the first embodiment. In the residue removal step 1, one substrate W was etched with no bias DC signal being applied, and the other substrate W was etched with the duty cycle of the bias DC signal set to 20%. The amounts of the residue 56 were compared.

FIGS. 10A and 10B are diagrams describing the processing conditions for the etching method according to the first embodiment in the third verification. FIGS. 10A and 10B show the periods in which the source RF signal, the bias RF signal, and the bias DC signal are provided for the period of one cycle at a frequency of 400 kHz during etching. The conditions are shown separately for the residue removal step 1 and the residue removal step 2. In the third verification, no bias DC signal was applied (FIG. 10A) and the duty cycle of the DC signal was set to 20% (FIG. 10B) during etching for the residue removal step 1. For the residue removal step 2, the duty cycles were both set to 10%.

In the third verification, the amount of the residue 56 on the substrate W was 1.67 nm with no bias DC signal being applied during etching (FIG. 10A), and the amount of the residue 56 on the substrate W was 1.1 nm for the duty cycle of 20% (FIG. 10B) in the residue removal step 1. This indicates that the etching method according to the first embodiment can reduce the amount of the residue 56 with the bias DC signal being applied in the residue removal step 1 as well.

In the above verifications, the etching method according to the first embodiment includes two steps, or specifically, the residue removal step 1 and the residue removal step 2. The residue removal step 1 is followed by the residue removal step 2 to etch the substrate W. However, the etching method according to the first embodiment is not limited to this example. The etching method according to the first embodiment may include three or more steps. The etching method according to the first embodiment may include no separate steps, and may etch the substrate W with a bias DC signal having a constant duty cycle during etching. The substrate W may be etched with the etching method according to the first embodiment alone or may be etched with the etching method according to the first embodiment in combination with other etching methods.

### Flowchart

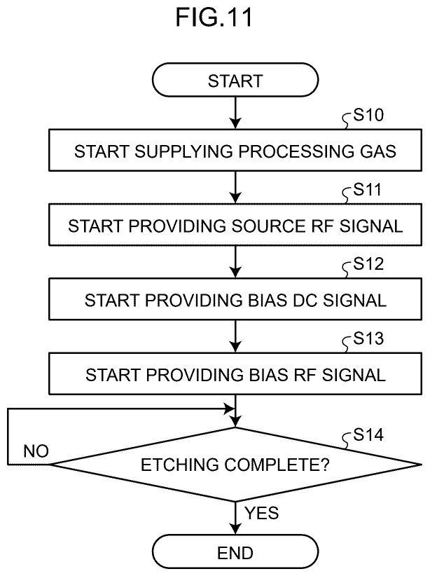

The procedure of etching including the etching method according to one or more embodiments of the present disclosure will now be described. FIG. 11 is a flowchart of an example order of etching according to the first embodiment. The etching in FIG. 11 is performed when the etching of the substrate W starts.

The controller 2 controls the gas supply 20 to start supplying a processing gas from the gas supply 20 into the plasma processing chamber 10 (step S10). The controller 2 controls the first RF generator 31a to start providing a source RF signal from the first RF generator 31a to form the processing gas in the plasma processing chamber 10 into a plasma (step S11). The controller 2 controls the bias DC generator 32a to start providing a bias DC signal from the bias DC generator 32a to the substrate support 11 (step S12). The controller 2 controls the second RF generator 31b to start providing a bias RF signal from the second RF generator 31b to the substrate support 11 in a manner superimposed on the bias DC signal (step S13). The processing in steps S11 to S13 may be performed in any order. In some embodiments, some or all of the steps in steps S11 to S13 may be performed as a single step.

The controller 2 determines whether the etching is complete (step S14). For example, when a predetermined condition for ending the etching is satisfied, the controller 2 determines that the etching is complete. When the etching is not complete (No in step S14), the processing advances to step S14 again. When the etching is complete (Yes in step S14), the controller 2 stops supplying the processing gas, the source RF signal, the bias DC signal, and the bias RF signal, and ends the process.

The etching according to the first embodiment can thus achieve higher verticality in the processing performance. The etching method according to the first embodiment can also reduce the residue 56.

The etching shown in FIG. 11 is a mere example, and is not limited to this example. The etching may include other steps. The etching may be performed as a part of another process. For example, when the etching includes multiple processes to be performed sequentially to etch the substrate W to a stop layer, the etching shown in FIG. 11 may be performed as a process for etching the substrate W to the stop layer. When performing the etching of the substrate W shown in FIGS. 2A to 3B, for example, the controller 2 may perform the etching shown in FIG. 11 to etch the bottom of the rectangular portion 55 reaching the underlying layer 50.

### Second Embodiment

A second embodiment will now be described. A plasma processing system according to the second embodiment has the same structure as the plasma processing system according to the first embodiment shown in FIG. 1, and will not be described.

The bias DC generator 32a periodically switches a negative DC voltage on and off to provide a pulsed bias DC signal.

The second RF generator 31b provides a bias RF signal during an off-time of the bias DC signal without providing the bias RF signal during an on-time of the bias DC signal.

The etching method according to the second embodiment does not provide, in a superimposed manner, a bias RF signal during an on-time in which the DC voltage of the bias DC signal is on and provides, in a superimposed manner, a bias RF signal during an off-time in which the DC voltage of the bias DC signal is off.

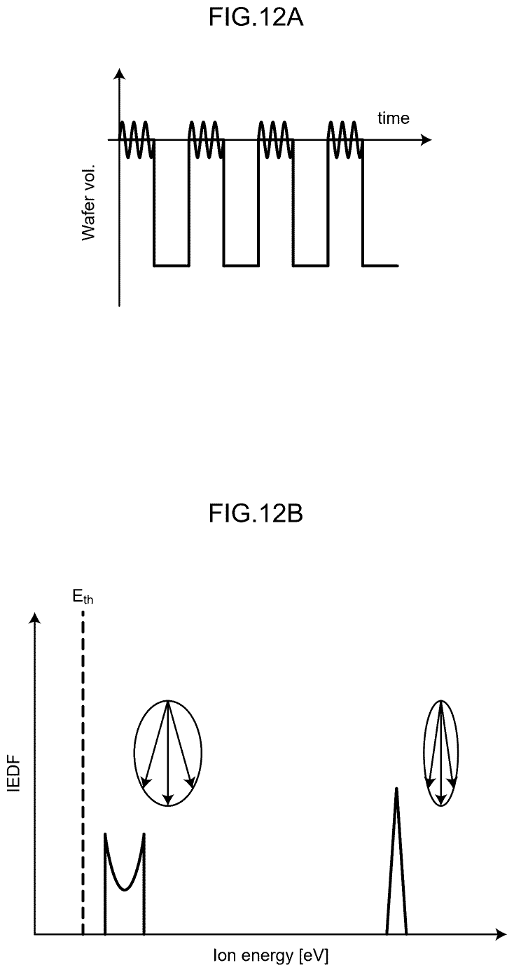

FIG. 12A is a graph showing an example change in the potential of the substrate W with the etching method according to the second embodiment. The bias RF signal is provided to the lower electrode in the base 1110 in a manner superimposed on the bias DC signal during an off-time of the bias DC signal. The potential of the substrate W thus changes rectangularly in response to changes in the bias DC signal and oscillates in response to the bias RF signal during the off-time.

FIG. 12B is a graph showing an example energy distribution of ions with the etching method according to the second embodiment. FIG. 12B is a schematic graph of the IEDF with the etching method according to the second embodiment. The horizontal axis indicates the energy of ions (eV), with higher energy rightward. The vertical axis indicates the number of ions, with more ions upward. FIG. 12B shows the threshold Eₜₕ of the ion energy used for etching the gate material 52.

The etching method according to the second embodiment has peaks at a higher energy level and a lower energy level.

With the etching method according to the second embodiment, the bias RF signal is not superimposed during an on-time of the bias DC signal. A higher peak thus appears at a higher energy level in a narrower energy width. The etching method according to the second embodiment has a peak at the higher energy level with an acute energy distribution. The etching method according to the second embodiment thus has higher verticality of ions and radicals, thus achieving higher verticality in the processing performance.

With the etching method according to the second embodiment, the bias RF signal is superimposed during an off-time of the bias DC signal. The peak at a lower energy level is also higher than or equal to the threshold Eₜₕ and has a wider peak width. The etching method according to the second embodiment can thus increase the incident angle of ions incident on the substrate W, and can efficiently remove the residue 56, thus reducing the residue 56.

The etching method according to either of the first and second embodiments can independently change the peak height and the peak energy at a higher energy level without changing the peak height and the peak energy at a lower energy level by changing the amplitude and the on-time of the bias DC signal.

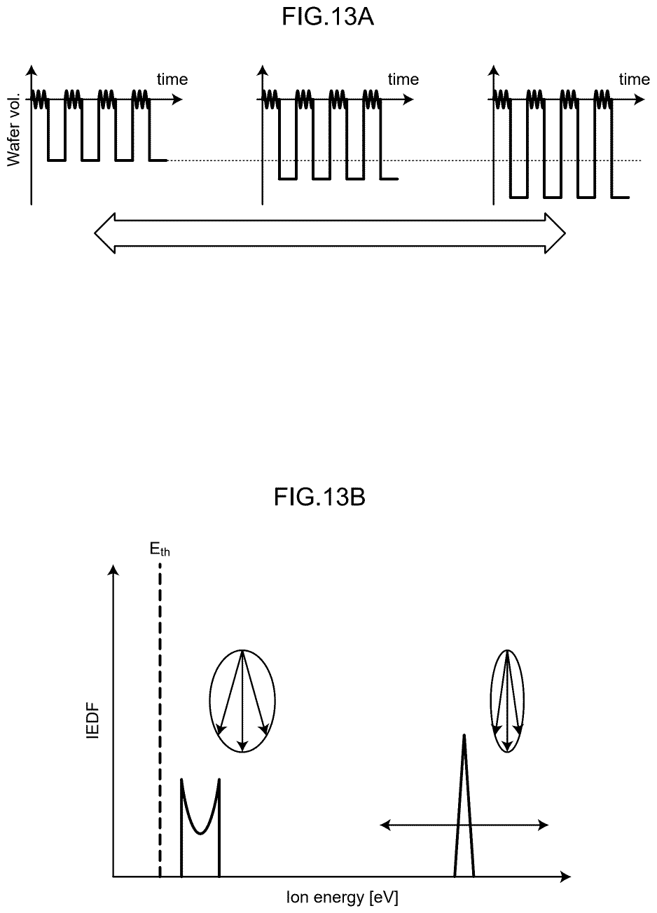

FIG. 13A is a graph showing changes in the potential of the substrate W in response to changes in the amplitude of the DC signal. FIG. 13A shows changes in the amplitude of the bias DC signal by changing the negative voltage during an on-time of the bias DC signal with the etching method according to the second embodiment. In FIG. 13A, changes in the potential of the substrate W increases rightward during an on-time as the negative voltage of the bias DC signal is increased during an on-time rightward. FIG. 13B is a graph showing changes in the energy distribution of ions in response to changes in the amplitude of the bias DC signal. FIG. 13B shows changes in the amplitude of the bias DC signal by changing the negative voltage during an on-time of the bias DC signal with the etching method according to the second embodiment. The energy of ions drawn toward the substrate W changes based on the potential of the substrate W. Changing the amplitude of the bias DC signal can thus change the energy range in which the peak appears at a higher energy level.

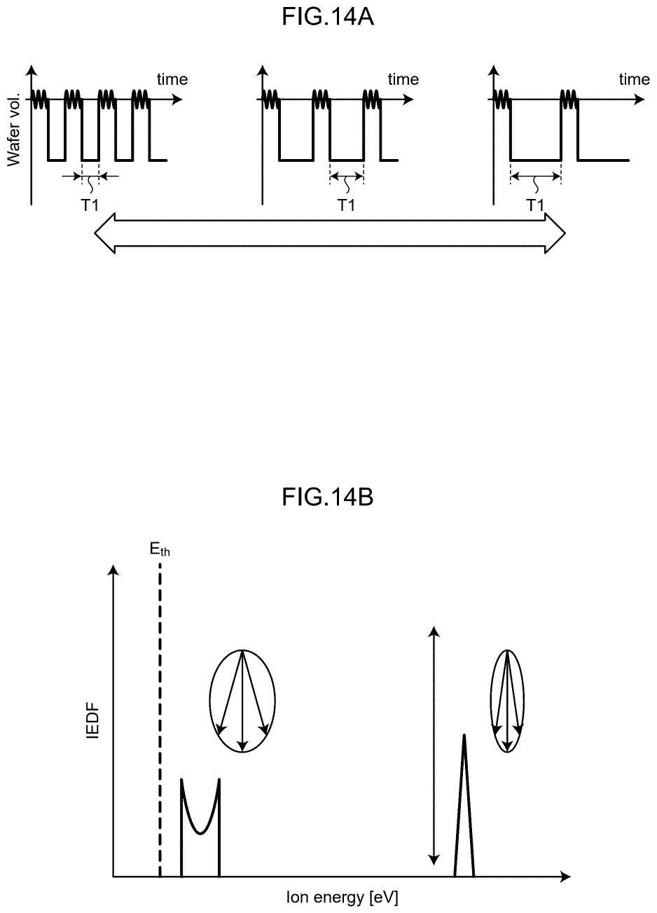

FIG. 14A is a graph showing changes in the potential of the substrate W in response to changes in an on-time of the bias DC signal. In FIG. 14A, the on-time of the bias DC signal is changed with the etching method according to the second embodiment. In FIG. 14A, the on-time of the bias DC signal is longer rightward, and a period T1 in which the substrate W has a negative potential is longer rightward. FIG. 14B is a graph showing changes in the energy distribution of ions in response to changes in the on-time of the bias DC signal. In FIG. 14B, the on-time of the bias DC signal is changed with the etching method according to the second embodiment. More ions are drawn toward the substrate W as the period in which the substrate W has a negative potential is longer. Changing the on-time of the bias DC signal can thus change the peak height at a higher energy level.

The etching method according to either of the first and second embodiments can independently change the peak height and the peak energy range at a lower energy level without changing the peak height and the peak energy at a higher energy level by changing the amplitude of the bias RF signal and the off-time of the bias DC signal.

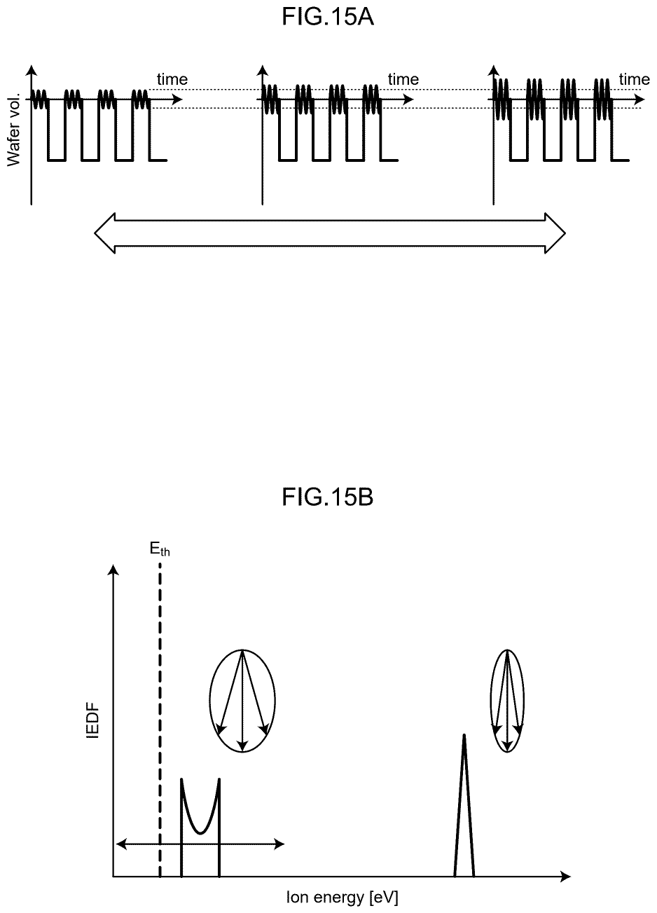

FIG. 15A is a graph showing changes in the potential of the substrate W in response to changes in the amplitude of the bias RF signal. In FIG. 15A, the amplitude of the bias RF signal is changed with the etching method according to the second embodiment. In FIG. 15A, the substrate W has a potential with a greater oscillation width during an off-time rightward by increasing the amplitude of the bias RF signal rightward. FIG. 15B is a graph showing changes in the energy distribution of ions in response to changes in the amplitude of the bias RF signal. In FIG. 15B, the amplitude of the bias RF signal is changed with the etching method according to the second embodiment. The energy of ions drawn toward the substrate W changes based on the potential of the substrate W. Changing the amplitude of the bias RF signal can thus change the energy range in which the peak appears at a lower energy level.

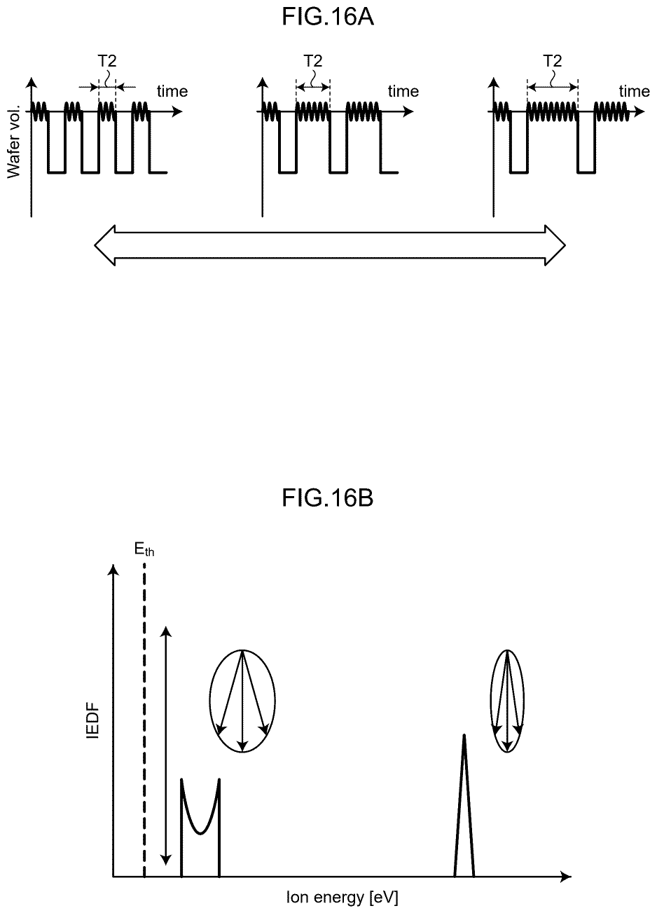

FIG. 16A is a graph showing changes in the potential of the substrate W in response to changes in an off-time of the bias DC signal. In FIG. 16A, the off-time of the bias DC signal is changed with the etching method according to the second embodiment. In FIG. 16A, the off-time of the bias DC signal is longer rightward, and a period T2 in which the potential of the substrate W is closer to zero is longer rightward. FIG. 16B is a graph showing changes in the energy distribution of ions in response to changes in the off-time of the bias DC signal. In FIG. 16B, the off-time of the bias DC signal is changed with the etching method according to the second embodiment. More ions are drawn toward the substrate W in the period T2 as the period T2 in which the substrate W is closer to zero is longer. Changing the off-time of the bias DC signal can thus change the peak height at a lower energy level.

The on-time and the off-time of the bias DC signal can be changed by changing the period and the duty cycle of the bias DC signal. The etching method according to either of the first and second embodiments can thus adjust the energy distribution of ions incident on the substrate W by changing the period, the duty cycle, and the amplitude of the bias DC signal and the amplitude of the bias RF signal. For example, the etching method according to the first and second embodiments can adjust the peak heights at a lower energy level and a higher energy level and the energy range in which the peak appears by changing the period, the duty cycle, and the amplitude of the bias DC signal and the amplitude of the bias RF signal.

The controller 2 may control the period, the duty cycle, and the amplitude of the bias DC signal and the amplitude of the bias RF signal during etching of the substrate W. For example, the etching of the substrate W shown in FIGS. 2A to 3B includes forming holes surrounded by the masks 53 and the fins 51a in the gate material 52. The controller 2 controls the period, the duty cycle, and the amplitude of the bias DC signal and the amplitude of the bias RF signal to form the holes in the gate material 52 through etching. For example, the controller 2 controls the period, the duty cycle, and the amplitude of the bias DC signal and the amplitude of the bias RF signal to cause the peak at a higher energy level to be higher and the peak at a lower energy level to be lower until the bottom of each hole reaches the underlying layer 50. The controller 2 controls the period, the duty cycle, and the amplitude of the bias DC signal and the amplitude of the bias RF signal to cause the peak at a lower energy level to be higher and the energy range in which the peak at a lower energy level appears to be wider after the bottom of the hole reaches the underlying layer 50. The plasma processing apparatus 1 can thus achieve higher verticality in the processing performance. The plasma processing apparatus 1 can also reduce the residue 56.

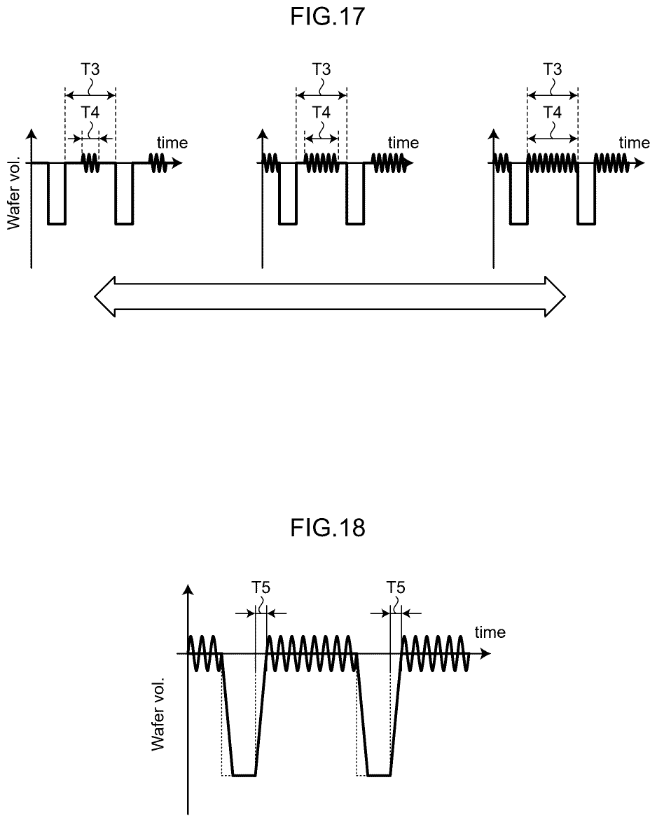

The etching method according to either of the first and second embodiments described above superimposes the bias RF signal throughout the off-time of the bias DC signal. However, the embodiments are not limited to the above examples. The etching method according to either of the first and second embodiments may superimpose the bias RF signal during a part of the off-time of the bias DC signal. FIG. 17 is a graph showing changes in the potential of the substrate W in response to changes in a superimposition period in which the bias RF signal is superimposed. As shown in FIG. 17, the etching method according to the second embodiment can change the peak height at a lower energy level based on the length of a superimposition period T4 in which the bias RF signal is superimposed during an off-time T3 of the bias DC signal.

The etching method according to either of the first and second embodiments described above superimposes the bias RF signal throughout the off-time of the bias DC signal. However, the embodiments are not limited to the above example. When the bias DC signal has poor rectangularity, the etching method according to either of the first and second embodiments may superimpose the bias RF signal after a transition period in which the potential of the substrate W changes in response to the switching of the bias DC signal on and off, rather than in the transition period. FIG. 18 is a graph showing changes in the potential of the substrate W in response to changes in the superimposition period T4 in which the bias RF signal is superimposed. The potential of the substrate W has a period T5 as a transition period in which the bias DC signal is switched off and approaches near zero. In FIG. 18, the bias RF signal remains off for the period T5 after the bias DC signal is switched off and is not superimposed on the bias DC signal. The bias RF signal is superimposed on the bias DC signal after the period T5. When the bias DC signal has poor rectangularity, the etching method according to either of the first and second embodiments superimposes the bias RF signal after the transition period, rather than in the transition period, allowing the peaks to appear at a lower energy level and a higher energy level.

The etching method according to either of the first and second embodiments described above is used for etching the substrate W shown in FIGS. 2A and 2B. However, the embodiments are not limited to the above example. The substrate W may be any substrate including an etching target film on the underlying layer. The etching target film may be, for example, an oxide film such as a silicon oxide film, a SiN film, an organic film, or a metal film such as a tungsten film. The underlying layer may be formed from any material having an etching selectivity over the etching target film described above. The etching method according to either of the first and second embodiments may be used for etching the holes in the target film on the substrate W until the holes reach the underlying layer.

### Effects

As described above, the plasma processing system (plasma processing apparatus) according to any of the above embodiments includes the plasma processing chamber 10, the substrate support 11, the gas supply 20, the first RF generator 31a (first RF power supply), the bias DC generator 32a (pulsed-voltage source), the second RF generator 31b (second RF power supply), and the controller 2. The substrate support 11 is located in the plasma processing chamber 10 to support the substrate W. The gas supply 20 supplies a processing gas into the plasma processing chamber 10. The first RF generator 31a provides a source RF signal (first RF power) for forming the processing gas in the plasma processing chamber 10 into a plasma. The bias DC generator 32a provides a bias DC signal (pulsed voltage) of a pulsed DC voltage to the substrate support 11. The second RF generator 31b provides the bias RF signal (second RF power) to the substrate support 11. During etching of the substrate W, the controller 2 performs control of the gas supply 20 to supply the processing gas into the plasma processing chamber 10, the first RF generator 31a to provide the source RF signal to form the processing gas in the plasma processing chamber 10 into a plasma, the bias DC generator 32a to provide the bias DC signal to the substrate support 11, and the second RF generator 31b to provide the bias RF signal in a manner superimposed on the bias DC signal. The plasma processing system according to the embodiment can reduce a residue.

The bias DC generator 32a periodically switches the negative DC voltage on and off and changes an on-time and an off-time in one cycle to change the duty cycle of the bias DC signal. The controller 2 controls the duty cycle of the bias DC signal to be 10 to 80%. The plasma processing system according to the embodiment can reduce a residue.

The controller 2 controls the duty cycle of the bias DC signal to 10 to 20%. The plasma processing system according to the embodiment can reduce a residue.

The substrate W includes the underlaying layer and the etching target film on the underlying layer. The controller 2 controls the duty cycle of the bias DC signal to be lower in response to the bottom of the hole etched in the target film being closer to the underlying layer. The plasma processing system according to the embodiment can thus reduce a residue on the bottom of the hole.

The bias DC generator 32a periodically switches the negative DC voltage on and off to provide the bias DC signal. The second RF generator 31b provides the bias RF signal during an off-time of the bias DC signal without providing the bias RF signal during an on-time of the bias DC signal. The plasma processing system according to the embodiment can reduce a residue. The plasma processing system according to the embodiment can achieve higher verticality in the processing performance.

The substrate W includes the underlaying layer and the etching target film on the underlying layer. The controller 2 performs the control described above when the bottom of the hole etched in the target film reaches the underlying layer. The plasma processing system according to the embodiment can thus reduce a residue on the bottom of the hole.

The substrate W includes the underlying layer 50, the fin structure 51 including multiple fins 51a on the underlying layer, the gate material 52 deposited on the fin structure 51, and the mask 53 on the gate material 52. The controller 2 performs the control described above when the gate material 52 deposited between the multiple fins 51a on the substrate W is etched until the underlying layer 50 is exposed. The plasma processing system according to the embodiment can thus reduce the residue 56 at the bottom of the hole (rectangular portion 55) through which the underlying layer 50 is exposed.

The bias DC generator 32 a provides a bias DC signal with a frequency of 100 to 1200 kHz. The plasma processing system according to the embodiment can thus achieve higher verticality in the processing performance.

The gate material is polycrystalline silicon. The underlying layer is a silicon oxide film. The plasma processing system according to the embodiment can thus reduce a residue on the bottom of the hole etched in the polycrystalline silicon and through which the silicon oxide film is exposed. The plasma processing system according to the embodiment can reduce a residue.

The controller 2 controls the period, the duty cycle, and the amplitude of the bias DC signal and the amplitude of the bias RF signal during etching of the substrate W. The plasma processing system according to the embodiment can thus adjust the heights of the peaks at a lower energy level and a higher energy level and the energy range in which each peak appears in the energy distribution of ions.

The substrate W includes the underlaying layer and the etching target film on the underlying layer. The controller 2 controls the period, the duty cycle, and the amplitude of the bias DC signal and the amplitude of the bias RF signal to cause, in the energy distribution of ions incident on the substrate W, a peak at a higher energy level to be higher and a peak at a lower energy level to be lower until the bottom of the hole etched in the target film reaches the underlying layer, and to cause a peak at a lower energy to be higher and the energy range in which the peak at the lower energy level appears to be wider after the bottom of the hole reaches the underlying layer. The plasma processing system according to the embodiment can reduce a residue. The plasma processing system according to the embodiment can achieve higher verticality in the processing performance.

Although one or more embodiments have been described above, the embodiments described herein are mere examples in all respects and should not be construed to be restrictive. The above embodiments may be implemented in various forms. The above embodiments may be eliminated, substituted, or modified in various manners without departing from the spirit and scope of the claims.

In the above embodiments, for example, plasma etching is performed on the semiconductor wafer as the substrate W. However, the embodiments are not limited to this example. The substrate W may be any substrate.

The embodiments described herein are mere examples in all aspects and should not be construed to be restrictive. The above embodiments may be implemented in various forms. The above embodiments may be eliminated, substituted, or modified in various manners without departing from the spirit and scope of the appended claims.

The technique according to the above aspect of the present disclosure reduces a residue.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

Reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C.

No claim element herein is to be construed under the provisions of 35 U.S.C. 112(f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The scope of the invention is indicated by the appended claims, rather than the foregoing description.

The embodiments described above will be further described below.

### Appendix 1

A plasma processing apparatus, comprising:
a chamber;
a substrate support in the chamber, the substrate support being configured to support a substrate;
a gas supply configured to supply a processing gas into the chamber;
a first radio-frequency power supply configured to supply first radio-frequency power to form the processing gas in the chamber into a plasma;
a pulsed-voltage source configured to apply a pulsed voltage being a pulsed direct current voltage to the substrate support;
a second radio-frequency power supply configured to supply second radio-frequency power to the substrate support; and
a controller configured to perform, during etching of the substrate, control of
   the gas supply to supply the processing gas into the chamber,
   the first radio-frequency power supply to supply the first radio-frequency power to form the processing gas in the chamber into a plasma,
   the pulsed-voltage source to apply the pulsed voltage to the substrate support, and
   the second radio-frequency power supply to supply the second radio-frequency power in a manner superimposed on the pulsed voltage.

### Appendix 2

The plasma processing apparatus according to appendix 1, wherein
the pulsed-voltage source periodically switches a negative direct current voltage on and off and changes a ratio of an on-time and an off-time in one cycle to change a duty cycle of the pulsed voltage, and
the controller controls the duty cycle of the pulsed voltage to be 10 to 80%.

### Appendix 3

The plasma processing apparatus according to appendix 2, wherein
the controller controls the duty cycle of the pulsed voltage to be 10 to 20%.

### Appendix 4

The plasma processing apparatus according to appendix 2 or appendix 3, wherein
the substrate includes an underlying layer and an etching target film on the underlying layer, and
the controller controls the duty cycle of the pulsed voltage to be lower in response to a bottom of a hole etched in the etching target film being closer to the underlying layer.

### Appendix 5

The plasma processing apparatus according to any one of appendixes 1 to 4, wherein
the pulsed-voltage source periodically switches a negative direct current voltage on and off to apply the pulsed voltage, and
the second radio-frequency power supply supplies the second radio-frequency power during an off-time of the negative direct current voltage without supplying the second radio-frequency power during an on-time of the negative direct current voltage.

### Appendix 6

The plasma processing apparatus according to any one of appendixes 1 to 5, wherein
the substrate includes an underlying layer and an etching target film on the underlying layer, and
the controller performs the control when a bottom of a hole etched in the etching target film reaches the underlying layer.

### Appendix 7

The plasma processing apparatus according to any one of appendixes 1 to 6, wherein
the substrate includes an underlying layer, a fin structure including a plurality of fins on the underlying layer, a gate material deposited on the fin structure, and a mask on the gate material, and
the controller performs the control when the gate material deposited between the plurality of fins on the substrate is etched until the underlying layer is exposed.

### Appendix 8

The plasma processing apparatus according to any one of appendixes 1 to 7, wherein
the pulsed-voltage source applies a pulsed voltage with a frequency of 100 to 1200 kHz.

### Appendix 9

The plasma processing apparatus according to appendix 7, wherein
the gate material is polycrystalline silicon.

### Appendix 10

The plasma processing apparatus according to appendix 7 or appendix 9, wherein the underlying layer is a silicon oxide film.

### Appendix 11

The plasma processing apparatus according to any one of appendixes 1 to 10, wherein
the controller controls a period, a duty cycle, and an amplitude of the pulsed voltage and an amplitude of the second radio-frequency power during etching of the substrate.

### Appendix 12

The plasma processing apparatus according to any one of appendixes 1 to 11, wherein
the substrate includes an underlying layer and an etching target film on the underlying layer, and
the controller controls a period, a duty cycle, and an amplitude of a bias direct current signal and an amplitude of a bias radio-frequency signal to cause, in an energy distribution of ions incident on the substrate, a peak at a higher energy level to be higher and a peak at a lower energy level to be lower until a bottom of a hole etched in the etching target film reaches the underlying layer, and to cause the peak at the low-energy level to be higher and an energy range in which the peak at the low-energy level appears to be wider after the bottom of the hole reaches the underlying layer.

### Appendix 13

An etching method implementable with a plasma processing apparatus, the apparatus including a chamber, a substrate support located in the chamber to support a substrate, a gas supply configured to supply a processing gas into the chamber, a first radio-frequency power supply configured to supply first radio-frequency power to form the processing gas in the chamber into a plasma, a pulsed-voltage source configured to apply a pulsed voltage being a pulsed direct current voltage to the substrate support, and a second radio-frequency power supply configured to supply second radio-frequency power to the substrate support, the method comprising:
during etching of the substrate,
   supplying, from the gas supply, the processing gas into the chamber;
   supplying, from the first radio-frequency supply, the first radio-frequency power to form the processing gas in the chamber into the plasma;
   applying, from the pulsed-voltage source, the pulsed voltage to the substrate support; and
   supplying, from the second radio-frequency power supply, the second radio-frequency power in a manner superimposed on the pulsed voltage.

What is claimed is:

1. A plasma processing apparatus, comprising:
a chamber;
a substrate support in the chamber, the substrate support to support a substrate;
a gas supply to supply a processing gas into the chamber;
a first radio-frequency power supply configured to supply first radio-frequency power to form the processing gas in the chamber into a plasma;
a pulsed-voltage source configured to apply a pulsed voltage being a pulsed direct current voltage to the substrate support;
a second radio-frequency power supply configured to supply second radio-frequency power to the substrate support; and
controller circuitry configured to perform, during etching of the substrate, control of
the gas supply to supply the processing gas into the chamber,
the first radio-frequency power supply to supply the first radio-frequency power to form the processing gas in the chamber into a plasma,
the pulsed-voltage source to apply the pulsed voltage to the substrate support, and
the second radio-frequency power supply to supply the second radio-frequency power in a manner superimposed on the pulsed voltage.

2. The plasma processing apparatus according to claim 1, wherein
the pulsed-voltage source periodically switches a negative direct current voltage on and off and changes a ratio of an on-time and an off-time in one cycle to change a duty cycle of the pulsed voltage, and
the controller circuitry controls the duty cycle of the pulsed voltage to be 10 to 80%.

3. The plasma processing apparatus according to claim 2, wherein
the controller circuitry controls the duty cycle of the pulsed voltage to be 10 to 20%.

4. The plasma processing apparatus according to claim 2, wherein
the substrate includes an underlying layer and an etching target layer on the underlying layer, and
the controller circuitry controls the duty cycle of the pulsed voltage to be lower in response to a bottom of a hole etched in the etching target layer being closer to the underlying layer.

5. The plasma processing apparatus according to claim 1, wherein
the pulsed-voltage source periodically switches a negative direct current voltage on and off to apply the pulsed voltage, and
the second radio-frequency power supply supplies the second radio-frequency power during an off-time of the negative direct current voltage without supplying the second radio-frequency power during an on-time of the negative direct current voltage.

6. The plasma processing apparatus according to claim 1, wherein
the substrate includes an underlying layer and an etching target layer on the underlying layer, and
the controller circuitry performs the control when a bottom of a hole etched in the etching target layer reaches the underlying layer.

7. The plasma processing apparatus according to claim 1, wherein
the substrate includes an underlying layer, a fin structure including a plurality of fins on the underlying layer, a gate material deposited on the fin structure, and a mask on the gate material, and
the controller circuitry performs the control when the gate material deposited between the plurality of fins on the substrate is etched until the underlying layer is exposed.

8. The plasma processing apparatus according to claim 1, wherein
the pulsed-voltage source applies a pulsed voltage with a frequency of 100 to 1200 kHz.

9. The plasma processing apparatus according to claim 7, wherein
the gate material is polycrystalline silicon.

10. The plasma processing apparatus according to claim 7, wherein
the underlying layer is a silicon oxide layer.

11. The plasma processing apparatus according to claim 1, wherein
the controller circuitry controls a period, a duty cycle, and an amplitude of the pulsed voltage and an amplitude of the second radio-frequency power during etching of the substrate.

12. The plasma processing apparatus according to claim 1, wherein
the substrate includes an underlying layer and an etching target layer on the underlying layer, and
the controller circuitry controls a period, a duty cycle, and an amplitude of a bias direct current signal and an amplitude of a bias radio-frequency signal to cause, in an energy distribution of ions incident on the substrate, a peak at a higher energy level to be higher and a peak at a lower energy level to be lower until a bottom of a hole etched in the etching target layer reaches the underlying layer, and to cause the peak at the lower energy level to be higher and an energy range in which the peak at the lower energy level appears to be wider after the bottom of the hole reaches the underlying layer.

13. An etching method implementable with a plasma processing apparatus, the method comprising:
during etching of a substrate that is supported by a substrate support located in a chamber of the plasma processing apparatus,
supplying, from a gas supply, processing gas into the chamber;
supplying, from a first radio-frequency supply, first radio-frequency power to form a processing gas in the chamber into a plasma;
applying, from a pulsed-voltage source, a pulsed voltage to the substrate support; and
supplying, from a second radio-frequency power supply, a second radio-frequency power in a manner superimposed on the pulsed voltage.

14. The plasma processing apparatus according to claim 1, wherein
the pulsed-voltage source periodically switches a negative direct current voltage on and off.

15. The plasma processing apparatus according to claim 1, wherein
the pulsed-voltage source periodically switches a negative direct current voltage on and off and changes a ratio of an on-time and an off-time in one cycle to change a duty cycle of the pulsed voltage.

16. The plasma processing apparatus according to claim 2, wherein
the substrate includes an underlying layer and an etching target layer on the underlying layer.

17. The plasma processing apparatus according to claim 1, wherein
the pulsed-voltage source periodically switches a negative direct current voltage on and off to apply the pulsed voltage.

18. The plasma processing apparatus according to claim 1, wherein
the substrate includes an underlying layer and an etching target layer on the underlying layer.

19. The plasma processing apparatus according to claim 1, wherein
the substrate includes an underlying layer and an etching target layer on the underlying layer, and
the controller circuitry controls a period, a duty cycle, and an amplitude of a bias direct current signal and an amplitude of a bias radio-frequency signal to cause, in an energy distribution of ions incident on the substrate, a peak at a higher energy level to be higher and a peak at a lower energy level to be lower until a bottom of a hole etched in the etching target layer reaches the underlying layer.

20. The etching method of claim 13, further comprising:
periodically switching, with the pulsed-voltage source, a negative direct current voltage on and off and changing a ratio of an on-time and an off-time in one cycle to change a duty cycle of the pulsed voltage; and
controlling the duty cycle of the pulsed voltage to be 10 to 80%.
